(19) United States
(12) Patent Application Publication
(10) Pub. No.: US 2026/0076119 A1
(43) Pub. Date: Mar. 12, 2026

(54) METHOD FOR ETCHING FEATURES USING HF GAS

(71) Applicant: Lam Research Corporation, Fremont, CA (US)

(72) Inventors: Eric A. HUDSON, Berkeley, CA (US); Leonid BELAU, Pleasanton, CA (US); Thorsten LILL, Kalaheo, HI (US)

(21) Appl. No.: 19/107,854

(22) PCT Filed: Sep. 8, 2023
(86) PCT No.: PCT/US2023/073737

§ 371 Date: Feb. 28, 2025

Related U.S. Application Data
(60) Provisional application No. 63/406,026, filed on Sep. 13, 2022.

(51) Int. Cl. H01L 21/311; C09K 13/08; H01J 37/32; H01L 21/027

(52) U.S. Cl. CPC H10P 50/283; C09K 13/08; H01J 37/32449; H01J 37/32724; H10P 50/73; H10P 76/20; H01J 2237/3346

(57) ABSTRACT

START PLACE STACK IN CHAMBER ON SUPPORT COOL SUPPORT FLOW HF ETCH GAS INTO CHAMBER FORUM ETCH GAST INTO PLASMA EXPOSE STACK TO PLASMA SELECTIVELY ETCH STACK REMOVE STACK FROM CHAMBER

### CROSS-REFERENCE TO RELATED APPLICATION

This application claims the benefit of priority of U.S. Application No. 63/406,026, filed Sep. 13, 2022, which is incorporated herein by reference for all purposes.

### BACKGROUND

The disclosure relates to a method of forming semiconductor devices on a semiconductor wafer. More specifically, the disclosure relates to etching a stack in the formation of memory or other semiconductor devices.

In forming semiconductor devices, etch layers may be etched to form memory holes or lines. Some semiconductor devices may be formed by etching a stack of bilayers of silicon oxide and silicon nitride (ONON) or bilayers of silicon oxide and polysilicon (OPOP). Such stacks may be used in memory applications, such as in forming three dimensional “negative and” gates (3D NAND). Other stacks comprising thicker layers of silicon oxide and thinner layers of silicon nitride may be used in other memory applications, such as forming dynamic random access memory (DRAM).

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack containing at least one of silicon oxide and silicon nitride below a mask is provided. A substrate support for supporting the stack in an etch chamber is cooled to a temperature below 0° C. An etch gas comprising a halogen containing component and HF gas is provided. A plasma is formed from the etch gas. Features are selectively etched in the stack with respect to the mask.

In another manifestation, an apparatus for processing a stack over a substrate with at least one of a silicon oxide layer and silicon nitride layer below a mask is provided. An etch chamber is provided. A substrate support supports a substrate inside the etch chamber. A temperature controller controls a temperature of the substrate support. An electrode provides RF power inside the etch chamber. An RF power source provides RF power to the electrode. A gas source provides an etch gas into the etch chamber where the gas source comprises a halogen containing component source and an HF gas source.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-B are schematic cross-sectional views of a stack processed according to an embodiment.

FIG. 3 is a schematic view of an etch chamber that may be used in an embodiment.

FIG. 4 is a schematic view of a computer system that may be used in practicing an embodiment.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Prior art ONON and OPOP etching technology, especially for holes, relies on low surface temperatures and a plasma chemistry with high fluorine (F) and hydrogen (H) radical densities. F radicals are mainly controlled using nitrogen trifluoride (NF₃) and sulfur hexafluoride (SF₆), with additional contributions from hydrofluorocarbon (CₓH_{y}F_{z}), carbon tetrafluoride (CF₄), octafluorocyclobutane (C₄F₈), and/or other fluorocarbon gases H radicals are mainly controlled by hydrogen gas (H₂), with additional contributions from hydrogen bromide (HBr) , methane (CH₄), and/or CₓH_{y}F_{z} gases. In the plasma, hydrogen fluoride (HF) is likely produced from a series of dissociation, recombination, and/or exchange reactions. However, the HF density is not directly controlled, since it depends on multiple mechanisms including electron induced reactions.

These etch conditions combine to produce a relatively high etch rate, high mask selectivity, and reasonably vertical etch profile, up to height to width aspect ratios of ˜60-70 in holes. However, when extending the process to higher aspect ratios (deeper etch), all of these advantages are degraded. This in turn limits the scaling of 3D NAND technology, where thicker stacks may be required to provide more layers of devices.

There is a significant challenge to control profile in the very high aspect ratio contact dielectric etch, specifically during cryogenic etching of 3D NAND pillar structure: large bow CD with small bottom CD. This is likely due to increased etch by-product accumulation close to the etch front that slows down a SiO₂ reactive ion etch (RIE). The most common method to increase the etch rate (ER) for a high aspect ratio is to increase ion energy and ion flux. This results in worse bow CD control (larger bow). Another common practice for increasing bottom CD and ER is to modify plasma chemistry. This approach causes other tradeoffs such as bow enlargement, capping, or non-circular holes.

In some embodiments, HF gas is used as a component in an etch gas. Without being bound by theory, the HF is believed to transport very efficiently to a high aspect ratio in holes or slits, as compared to H and F radicals. By introducing HF as a source gas, higher densities of HF can be produced in the plasma while reducing plasma densities of F and H. The resulting conditions deliver more etchant in high aspect ratio (HAR) features, promoting higher etch rates and enabling effective etching at higher aspect ratios. Additionally, the reduced F and H radical densities should reduce the etching of the hardmask and lateral erosion of the ONON sidewall, resulting in higher etch selectivity, better mask CD control, and reduced bowing of the ONON profile.

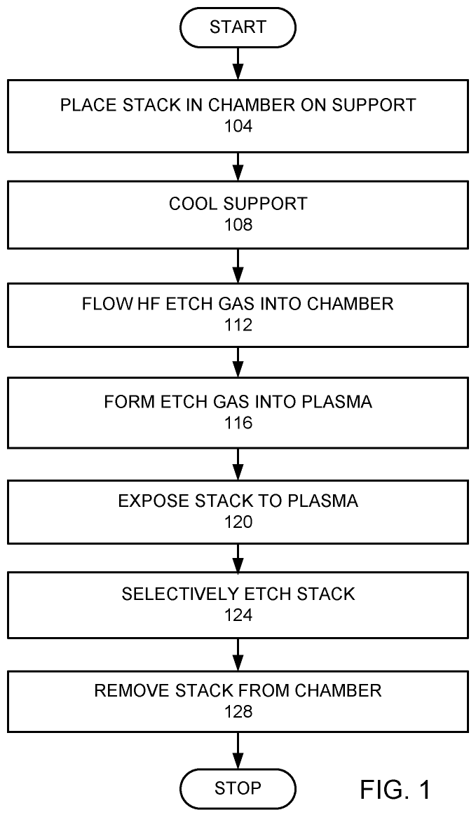

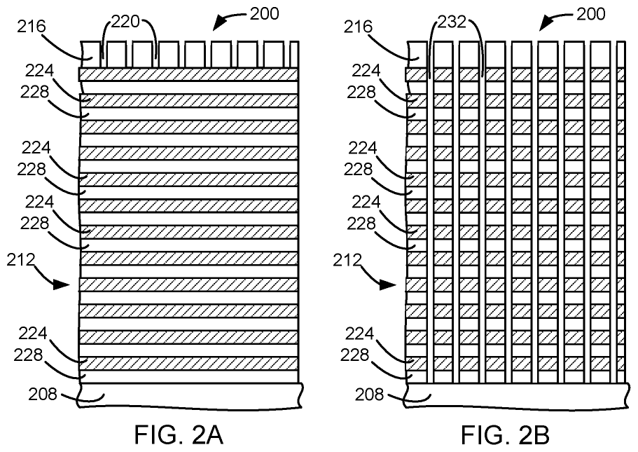

To facilitate understanding, FIG. 1 is a high level flow chart that may be used in some embodiments. In some embodiments, a stack is placed in an etch chamber on a substrate support (step 104). In some embodiments, the stack is disposed below a carbon containing patterned mask. In some embodiments, the carbon containing mask is an amorphous carbon mask. FIG. 2A is a schematic cross-sectional view of a stack 200 used in an embodiment. In some embodiments, the stack comprises a substrate 208 under a plurality of bilayers 212, which is disposed below a carbon containing patterned mask 216. One or more layers may be disposed between the substrate 208 and the plurality of bilayers 212 or the plurality of bilayers 212 and the carbon containing patterned mask 216. However, some embodiments do not have a silicon containing layer above or below the plurality of bilayers 212. The carbon containing patterned mask 216 may be amorphous carbon. In some embodiments, the patterned mask pattern provides mask features 220 for high aspect ratio contacts. In some embodiments, the mask features are formed before the substrate is placed in the etch chamber. In other embodiments, the mask features 220 are formed while the substrate is in the etch chamber. In some embodiments, the plurality of bilayers 212 are bilayers of a layer of silicon oxide 224 and a layer of silicon nitride 228. In some embodiments, the stack may comprise repeating sequences of 3 or more layers.

The substrate support is cooled to a temperature below 0° C. (step 108). In some embodiments, the substrate support is cooled to a temperature below −20°. The cooling of the substrate support causes the stack to be cooled, providing an etch process at cryogenic temperatures.

An etch gas comprising a halogen containing component and HF gas is provided (step 112). In some embodiments, the etch gas comprises a halogen containing component, HF gas, and a hydrofluorocarbon containing component. In some embodiments, the etch gas further comprises an inert bombardment gas, such as argon (Ar), helium (He), krypton (Kr), neon (Ne), xenon (Xe), or nitrogen (N₂). In some embodiments, the inert bombardment gas provides ions for ion bombardment to facilitate etching. In some embodiments, the halogen containing component comprises at least one of chlorohydrocarbon CₓH_{y}Cl_{z}, silicon tetrachloride (SiCl₄), bromine trichloride (BCl₃), nitrogen trifluoride (NF₃), C₄F₈, octafluoropropane (C₃F₈), hexafluoro-1,3-butadiene (C₄F₆), sulfur hexafluoride (SF₆), carbon tetrafluoride (CF₄), chlorine (Cl₂), hydrogen bromide (HBr), trifluoroiodomethane (CF₃I), fluoromethane (CH₃F), difluoromethane (CH₂F₂), hydrochloric acid (HCl), or trifluoromethane (CHF₃). In some embodiments, the etch gas further comprises at least one of a carbonyl sulfide (COS), hydrogen sulfide (H₂S), a hydrogen containing gas, methane (CH₄), and hydrogen (H₂). In some embodiments, the etch gas may comprise 0 -200 sccm CH₂F₂, 1-1000 sccm HF, 0-200 sccm HBr, and 0-200 sccm NF₃. In this example, a pressure of 5 to 60 mTorr is provided. In some embodiments, the halogen containing component may comprise a chlorine or bromine containing component.

The etch gas is formed into an etch plasma (step 116). This may be accomplished by providing an excitation RF with a frequency of 60 MHz at 200 to 25000 watts. In some embodiments, the RF power is in the range of 0 to 15000 watts at a frequency of 60 MHz. The stack 200 is exposed to the plasma (step 120). A bias with a magnitude of at least about 400 volts is provided. In some embodiments, the high bias is provided by providing an RF with a frequency of 400 kHz at 2 kW to 150 kW. The bias causes ions to be accelerated to the stack 200 causing the selective etching of high aspect ratio etch features into the stack 200 with respect to the carbon containing patterned mask (step 124). In some embodiments, an RF power that is either continuous or pulsed RF power with a peak power in the range of 3 kW to 150 kW may be used for both excitation RF power using a higher frequency and bias RF power using a lower frequency. The plasma is maintained for 180 to 4800 seconds. The etch is able to etch both the silicon oxide and silicon nitride layers. After the etch is completed, the substrate is then removed from the etch chamber (step 128).

FIG. 2B is a cross-sectional view of the stack 200 after the contacts 232 have been etched. The contacts are high aspect ratio contacts. Preferably, the high aspect ratio contacts have a height to CD width ratio of greater than 40:1. More preferably, the contacts have an etch depth to feature CD width aspect ratio of greater than 100:1.

The etch process is able to selectively etch the silicon oxide and silicon nitride layers with respect to amorphous carbon with a selectivity of greater than 3:1 while etching high aspect ratio features. Some embodiments allow the etching of high aspect features with controlled CD, hole shape, capping, and tapering. In addition, some embodiments allow the use of a carbon containing patterned mask, such as amorphous carbon, which reduces costs and defects.

In some embodiments, at cryogenic temperatures, the HF gas may act as both an etchant and passivant. By adding HF gas to the etch gas, the concentration of HF gas in the etch plasma with respect to hydrogen radicals and fluorine radicals increases and the concentration of hydrogen radicals and fluorine radicals with respect to the concentration of HF is decreased. Decreasing the concentration of hydrogen radicals and fluorine radicals reduces the etching of the etch mask. Without being bound by theory, it is believed that the HF gas at low temperatures may be adsorbed on surfaces of the etch features. The adsorption increases the etchant density of HF on the etch front, increasing etching at the etch front. In addition, the density of fluorine is increased at the etch front without increasing the density of halogen radicals, increasing the fluorine neutral to radical ratio.

In some embodiments, the adsorbed HF gas reacts with silicon nitride and possibly nitrogen to form salts, such as ammonium fluoride and ammonium fluorosilicate. In some embodiments, the salts provide sidewall passivation. Thus, the HF gas not only etches the etch fronts, but the HF may also provide sidewall passivation. Since the directional ions do not strike the sidewalls with high energy, the sidewall passivation is able to protect the sidewalls and reduce undesirable bowing.

In some embodiments, the stack is cooled to a temperature below 20° C. In some embodiments, the substrate support is cooled to a temperature of below −20° C. In some embodiments, the substrate support is cooled to a temperature between −80° C to 0° C. to provide an improved process. In some embodiments, the substrate support is cooled to a temperature between −200° C. to −20° C. In some embodiments, the substrate support is cooled to a temperature between −60° C. to −40° C.

In some embodiments, the stack comprises one or more layers of at least one of silicon oxide and silicon nitride. In some embodiments, the stack is a single layer of silicon oxide or silicon nitride. In some embodiments, the stack comprises alternating layers of silicon oxide and polysilicon (OPOP). In some embodiments, the stack comprises repeating units of 2 or more layers comprising 2 or more materials.

In some embodiments, the ONON stack may be etched to form contact holes, channel holes, or trenches in making a 3D NAND memory device. Other embodiments may etch OPOP (alternating layers of SiO₂ and poly-silicon) stacks to form contact holes, channel holes, or trenches in making a 3D NAND memory devices. Other embodiments may be used for DRAM Capacitor etching. The capacitor etch may have a depth of more than 0.8 microns with a small CD providing a high aspect ratio feature in silicon oxide. Other embodiments provide for a CD less than 95 nm with an etch depth of greater than 8 microns, providing features with a depth to width aspect ratio of at least 80:1.

In some embodiments, the providing the etch gas and the ion etching may be provided as sequential steps in a cyclical process. Providing the etch gas simultaneously with the ion etching provides a faster process than the sequential cyclical process.

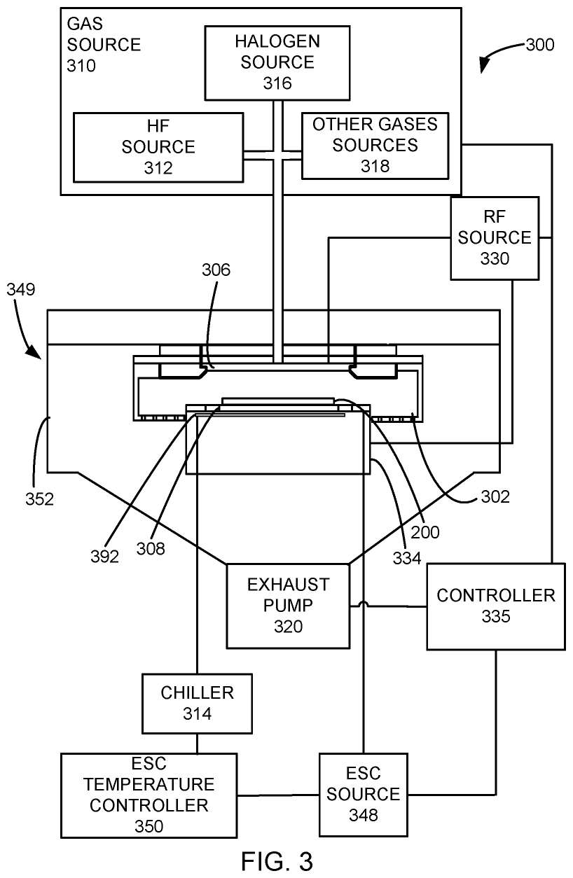

FIG. 3 is a schematic view of an etch reactor that may be used in an embodiment. In one or more embodiments, an etch reactor 300 comprises a gas distribution plate 306 providing a gas inlet and an electrostatic chuck (ESC) 308, within an etch chamber 349, enclosed by a chamber wall 352. Within the etch chamber 349, a stack 200 is positioned over the ESC 308, where the ESC 308 is also a substrate support. The ESC 308 may provide a bias from the ESC source 348. An etch gas source 310 is connected to the etch chamber 349 through the gas distribution plate 306. In some embodiments, the etch gas source 310 comprises an HF gas source 312, a halogen containing component source, and a source of other gases 318, such as a hydrogen containing component source and a fluorocarbon containing component source. An ESC temperature controller 350 is connected to a chiller 314. The chiller 314 is able to cool the ESC 308 to a temperature of less than 0° C. In this embodiment, the chiller 314 provides a coolant to channels 392 in or near the ESC 308. A radio frequency (RF) power source 330 provides RF power to a lower electrode and/or an upper electrode, which in this embodiment are the ESC 308 and the gas distribution plate 306. In some embodiments, a non-RF power source, such as a pulsed DC power source, may replace or be used with the RF power source 330 for controlling the plasma. In an exemplary embodiment, 400 kilohertz (kHz), 60 megahertz (MHz), and optionally 2 MHZ, 27 MHz power sources make up the RF power source 330 and the ESC source 348. In this embodiment, the upper electrode is grounded. In this embodiment, one generator is provided for each frequency. In other embodiments, the generators may be in separate RF sources or separate RF generators may be connected to different electrodes. For example, the upper electrode may have inner and outer electrodes connected to different RF sources. Other arrangements of RF sources and electrodes may be used in other embodiments. The RF power may be continuous or pulsed. A controller 335 is controllably connected to the RF power source 330, the ESC source 348, an exhaust pump 320, and the etch gas source 310. An example of such an etch chamber is the Exelan Flex® dielectric etch system or Vantex® dielectric etch system manufactured by Lam Research Corporation of Fremont, CA. The etch chamber can be a CCP (capacitively coupled plasma) reactor or an ICP (inductively coupled plasma) reactor, where the electrode may be a coil.

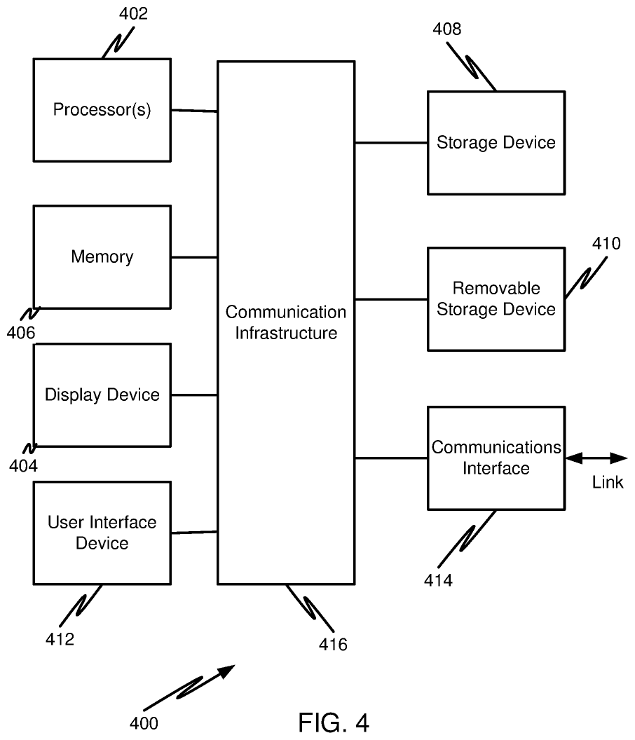

FIG. 4 is a high level block diagram showing a computer system 400, which is suitable for implementing a controller 335 used in embodiments. The computer system may have many physical forms ranging from an integrated circuit, a printed circuit board, and a small handheld device up to a huge supercomputer. The computer system 400 includes one or more processors 402 and further can include an electronic display device 404 (for displaying graphics, text, and other data), a main memory 406 (e.g., random access memory (RAM)), a storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

The information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer readable code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

In some embodiments, liquid nitrogen is used as a coolant that is flowed through the ESC 308 to provide cooling. In other embodiments, liquid Vertel Sinera™ manufactured by DuPont Corporation of Wilmington, DE may be used as the coolant.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for etching features in a stack containing at least one of silicon oxide and silicon nitride below a mask, comprising:
cooling a substrate support for supporting the stack in an etch chamber to a temperature below 0° C;
providing an etch gas comprising a halogen containing component and HF gas;
generating a plasma from the etch gas; and
selectively etching features in the stack with respect to the mask.

2. The method, as recited in claim 1, wherein the etch gas further comprises a hydrofluorocarbon containing component.

3. The method, as recited in claim 1, wherein the mask is a carbon containing mask.

4. The method, as recited in claim 1, wherein the etch gas further comprises an inert bombardment gas comprising at least one of He, Ne, Ar, Kr, Xe, and N₂.

5. The method, as recited in claim 1, wherein the halogen containing component, comprises at least one of a chlorohydrocarbon, SiCl₄, BCl₃, NF₃, C₄F₈, C₃F₈, C₄F₆, SF₆, CF₄, Cl₂, HBr, CF₃I, CH₃F, CH₂F₂, CHF₃, and HCl.

6. The method, as recited in claim 1, wherein the etch gas further comprises at least one of hydrogen containing gases, H₂, COS, H₂S, and CH₄.

7. The method, as recited in claim 1, wherein the substrate support is cooled to a temperature below −20° C.

8. The method, as recited in claim 1, further comprising providing an RF power with a peak power in a range of 3 kW to 150 kW.

9. The method, as recited in claim 1, wherein the mask is a carbon containing mask and wherein the stack includes a plurality of alternating silicon oxide and silicon nitride layers.

10. The method, as recited in claim 1, wherein the mask is a carbon containing mask and wherein the stack includes a plurality of alternating silicon oxide and polysilicon layers.

11. The method, as recited in claim 1, wherein the mask is a carbon containing mask and wherein the stack comprises at least one layer of silicon oxide.

12. The method, as recited in claim 1, wherein the mask is an amorphous carbon mask.

13. An apparatus for processing a stack over a substrate with at least one of a silicon oxide layer and silicon nitride layer below a mask, comprising:
an etch chamber;
a substrate support for supporting a substrate inside the etch chamber;
a temperature controller for controlling a temperature of the substrate support;
an electrode for providing RF power inside the etch chamber;
an RF power source for providing RF power to the electrode; and
a gas source that provides an etch gas into the etch chamber, comprising:
a halogen containing component source; and
an HF gas source.

14. The apparatus, as recited in claim 13, further comprising a controller controllably connected to the gas source, the RF power source, and the temperature controller, comprising:
a processor; and
computer readable media with computer readable code, wherein the computer readable code comprises:
computer readable code for cooling the substrate support to a temperature of no more than 0° C.;
computer readable code for providing an etch gas comprising a halogen containing component from the halogen containing component source and HF gas from the HF gas source;
computer readable code for providing RF power for generating a plasma from the etch gas; and
computer readable code for generating a bias.

15. The apparatus, as recited in claim 13, wherein the halogen containing component source comprises at least one of a SiCl₄, BCl₃, NF₃, C₄F₈, C₃F₈, C₄F₆, SF₆, CF₄, Cl₂, HBr, CF₃I, CH₃F, CH₂F₂, CHF₃, and HCl source.

16. The apparatus, as recited in claim 13, wherein the gas source further comprises an inert bombardment gas source.

17. The apparatus, as recited in claim 13, wherein the gas source further comprises at least one of an H₂, COS, H₂S, and CH₄ source.

18. The apparatus as recited in claim 13, further comprising a non-RF power source for controlling plasma in the etch chamber.
